(19) United States
(12) Patent Application Publication
(10) Pub. No.: US 2025/0109263 A1
(43) Pub. Date: Apr. 3, 2025

(54) STRETCHABLE INSULATING FILM, METHOD OF MANUFACTURING THE SAME, AND ELECTRONIC DEVICE INCLUDING SAME

(71) Applicants: Samsung Electronics Co., Ltd., Suwon-si (KR); KOREA ADVANCED INSTITUTE OF SCIENCE AND TECHNOLOGY, Daejeon (KR)

(72) Inventors: Joo Young KIM, Suwon-si (KR); Sung Gap IM, Daejeon (KR); Juyeon KANG, Daejeon (KR); Sung-Gyu KANG, Suwon-si (KR); Yasutaka KUZUMOTO, Suwon-si (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 18/775,413

(22) Filed: Jul. 17, 2024

(30) Foreign Application Priority Data
Jul. 18, 2023 (KR) 10-2023-0092986

(51) Int. Cl. C08J 5/18; B05D 1/00; C08J 7/04; H01L 21/02; H01L 29/786; H01L 33/56

(52) U.S. Cl. CPC C08J 5/18; B05D 1/60; C08J 7/04; H01L 21/02118; H01L 29/78603; H01L 33/56; B05D 2201/02; B05D 2518/10; C08J 2313/00; C08J 2483/04

(57) ABSTRACT

A stretchable insulating film may include a first insulating layer having stretchability and a second insulating layer on the first layer and having non-stretchability. The first insulating layer may include an elastomer and the second insulating layer may include a cyclic siloxane polymer framework. An electronic device may include the stretchable insulating film. A method of manufacturing the stretchable insulating film may include forming the first insulating layer and forming the second insulating layer. The forming the first insulating layer may include coating a composition including the elastomer or depositing the elastomer. The forming the second insulating layer may include injecting a cyclic siloxane monomer and an initiator on the first insulating layer into a reactor equipped with a heat source and performing a polymerization reaction by low-temperature vapor deposition.

### CROSS-REFERENCE TO RELATED APPLICATION

This application claims priority to and the benefit of Korean Patent Application No. 10-2023-0092986, filed in the Korean Intellectual Property Office on Jul. 18, 2023, the entire contents of which are incorporated herein by reference.

### BACKGROUND

### 1. Field

Example embodiments relate to stretchable insulating films, methods of manufacturing the same, and electronic devices including the same.

### 2. Description of the Related Art

In recent years, research on a stretchable display device or a bio-attachable device such as a smart skin device, a soft robot, and a biomedical device has been conducted. In addition to electrical properties, these devices should have stretchability in an arbitrary direction according to external movements, and at the same time should be able to maintain their original performance after being restored, and thus a new material suitable for this is required.

### SUMMARY

The substrate, semiconductor, insulator, and electrode materials that make up the stretchable device as described above are all required to have stretchability.

Conventional stretchable insulating films may be manufactured by coating a substrate (film) with a composition including an elastomer such as SEBS (styrene-ethylene-butylene-styrene) or PDMS (polydimethylsiloxane), and an azide-based curing agent, followed by hardening through UV irradiation and heat treatment (S. Wang et al., Nature 555, p 83-88 (2018)). However, the insulating film manufactured by this method is based on a solution process, and chemical changes and thermal deformation of the lower substrate (film) may be caused as photo-curing or thermal curing occurs after coating.

In addition, in the case of inorganic insulating films based on SiOₓ, SiNₓ, and AIOₓ, a self-assembled monolayer (SAM) is formed using ODTS (octadecyltrichlorosilane), ODTMS (octadecyltrimethoxysilane), etc. on the surface of the insulating film in order to increase charge mobility by improving the alignment of organic semiconductor molecules in contact with the insulating film. However, elastomers such as SEBS and PDMS, which are widely used as stretchable insulating films, do not have oxide structures such as Si—O, Al—O, etc. that exist in inorganic insulating films, and thus they cannot form self-assembled monolayers through chemical reactions with SAM materials such as ODTS and ODTMS. Because of this, there is a limit to improving the charge mobility characteristics of devices using organic semiconductors. In order to solve this problem, when inorganic materials such as SiOₓ, SiNₓ, and AIOₓ are deposited and coated on an elastomer film, the elastomer may be damaged by plasma, heat, and solvents during the deposition process. Even if these process limitations are overcome and an insulating film is manufactured by depositing an inorganic material on an elastomer film, when such an insulating film is stretched, even under very small strain conditions (approximately 5% or more), the inorganic material may peel off or cracks may occur, making it difficult to maintain stretchability and insulating properties.

Therefore, there is a need for an insulating film that can improve the charge mobility characteristics of the device by ensuring stretchability and insulating properties while enabling the formation of a self-assembled monolayer on the surface.

Some example embodiments provide a stretchable insulating film that has improved or excellent stretchability and insulating properties and can provide a surface on which a self-assembled monolayer can be formed.

Some example embodiments provide a method for manufacturing the stretchable insulating film.

Some example embodiments provide an electronic device including the stretchable insulating film.

According to some example embodiments, a stretchable insulating film may include a first insulating layer having stretchability and a second insulating layer on the first layer and having non-stretchability, wherein the first insulating layer may include an elastomer and the second insulating layer may include a cyclic siloxane polymer framework.

In some embodiments, the elastomer may include an organic elastomer, an organic-inorganic elastomer, or any combination thereof.

In some embodiments, the elastomer may include, for example, at least one of a substituted or unsubstituted polyorganosiloxane such as polydimethylsiloxane; an elastomer having a substituted or unsubstituted butadiene moiety such as styrene-ethylene-butylene-styrene (SEBS), styrene-ethylene-propylene-styrene (SEPS), styrene-butadiene-styrene (SBS), styrene-isoprene-styrene (SIS), or styrene-isobutylene-styrene (SIBS); an elastomer having an urethane moiety; an elastomer having an acrylic moiety; an elastomer having an ester moiety; an elastomer including an amide moiety; an elastomer including an olefin moiety; or any combination thereof.

In some embodiments, the first insulating layer may include the elastomer having the ester moiety and the elastomer having the ester moiety may include a polymer prepared by polymerizing an acrylic monomer represented by Chemical Formula 1A.

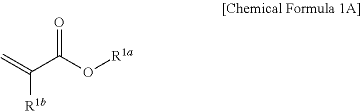

In Chemical Formula 1A, R^{1a} may be a substituted or unsubstituted C1 to C20 alkyl group, a substituted or unsubstituted C2 to C20 alkenyl group, or a substituted or unsubstituted C2 to C20 alkynyl group, and

R^{1b} may be hydrogen or a C1 to C6 alkyl group.

In some embodiments, in the substituted or unsubstituted C1 to C20 alkyl group, the substituted or unsubstituted C2 to C20 alkenyl group, or the substituted or unsubstituted C2 to C20 alkynyl group of R^{1a} of Chemical Formula 1A, at least one methylene (—CH₂—) group may be replaced by ether (—O—), sulfide (—S—), sulfonyl (—S(═O)₂—), carbonyl (—C(═O)—), sulfoxide (—S(═O)—), ester (—C(═O)O—), amide (—C(═O)NR—) (wherein R is hydrogen, a C1 to C10 linear or branched alkyl group, or a C2 to C10 linear or branched alkenyl group), imine (—NR—) (wherein R is hydrogen, a C1 to C10 linear or branched alkyl group, or a C2 to C10 linear or branched alkenyl group), phosphate (—P(═O)(OR)O₂—) (wherein R is hydrogen, a C1 to C10 linear or branched alkyl group, or a C2 to C10 linear or branched alkenyl group), or any combination thereof.

In some embodiments, in Chemical Formula 1A, R^{1a} may be: a C1 to C20 linear or branched alkyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof; a C2 to C20 linear or branched cyanoalkenyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof; or a C2 to C20 linear or branched cyanoalkynyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof.

In some embodiments, the first insulating layer may include the elastomer having the ester moiety and the elastomer having the ester moiety may be a polymer prepared by copolymerizing the acrylic monomer represented by Chemical Formula 1A and an alkenyl group-containing monomer.

In some embodiments, the alkenyl group-containing monomer may be a compound represented by Chemical Formula 2A or 2B.

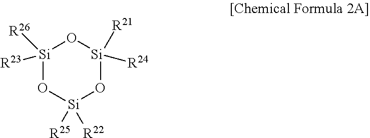

In Chemical Formula 2A,

R²¹ to R²⁶ each independently may be hydrogen, a substituted or unsubstituted C1 to C20 linear or branched alkyl group or a substituted or unsubstituted C2 to C20 alkenyl group, provided at least one of R²¹ to R²⁶ is a substituted or unsubstituted C2 to C20 alkenyl group.

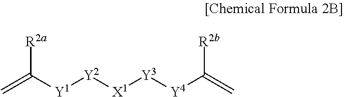

In Chemical Formula 2B,
X¹ may be —O—, —(CR^{x}R^{y})ₙ₁— (wherein R^{x} and R^{y} are each independently hydrogen or a substituted or unsubstituted C1 to C20 alkyl group, and n1 is an integer of 1 to 20), a C4 to C10 cycloalkylene group, a C3 to C10 heterocycloalkylene group, a C6 to C10 arylene group, a C3 to C10 heteroarylene group, or phosphate (—P(=O)(OR)O₂—) (wherein R is hydrogen, a C1 to C10 linear or branched alkyl group, or a C2 to C10 linear or branched alkenyl group),
Y¹ to Y⁴ each independently may be ether (—O—), carbonyl (—C(═O)—), ester (—C(═O)O—), or —(CR^{x}R^{y})ₙ₂— (wherein R^{x} and R^{y} are each independently hydrogen or a substituted or unsubstituted C1 to C20 alkyl group, and n2 is an integer of 1 to 20),
R^{2a} and R^{2b} may each independently be hydrogen or a C1 to C6 alkyl group.

In some embodiments, the alkenyl group-containing monomer may be the compound represented by Chemical Formula 2B, and in Chemical Formula 2B, X¹ may be —(CR^{x}R^{y})ₙ₁— and at least one of Y¹ to Y⁴ may be —(CR^{x}R^{y})ₙ₂—. In Chemical Formula 2B, when n1 or n2 is 3 or more and 20 or less, at least one CR^{x}R^{y} may be replaced by ether (—O—), sulfide (—S—), sulfonyl (—S(═O)₂—), carbonyl (—C(═O)—), sulfoxide (—S(═O)—), ester (—C(═O)O—), amide (—C(═O)NR—) (wherein R is hydrogen, a C1 to C10 linear or branched alkyl group, or a C2 to C10 linear or branched alkenyl group), imine (—NR—) (wherein R is hydrogen, a C1 to C10 linear or branched alkyl group, or a C2 to C10 linear or branched alkenyl group), phosphate (—P(═O)(OR)O₂—) (wherein R is hydrogen, a C1 to C10 linear or branched alkyl group, or a C2 to C10 linear or branched alkenyl group), or any combination thereof.

In some embodiments, the elastomer may include the elastomer having the ester moiety and the elastomer having the ester moiety may be prepared by polymerizing a carboxylic acid monomer and a hydroxyl group-containing monomer.

In some embodiments, the cyclic siloxane polymer framework may include a structural unit represented by Chemical Formula 3.

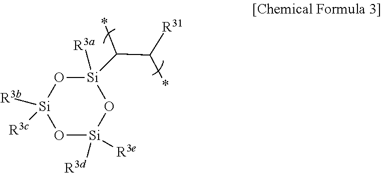

In Chemical Formula 3,
R^{3a} to R^{3e} each independently may be hydrogen, a substituted or unsubstituted C1 to C20 alkyl group, a substituted or unsubstituted C2 to C20 alkenyl group, a substituted or unsubstituted C6 to C20 aryl group, a substituted or unsubstituted C3 to C20 heteroaryl group, a substituted or unsubstituted C3 to C20 cycloalkyl group, or a substituted or unsubstituted C3 to C20 heterocycloalkyl group, and
R³¹ may be hydrogen or a C1 to C6 alkyl group.

In some embodiments, in Chemical Formula 3, at least one of R^{3b} and R^{3d} may be a group linking Si with the polymer main chain.

In some embodiments, at the interface between the first insulating layer and the second insulating layer, the cyclic siloxane polymer may form a structure partially penetrated into the elastomer in a form of a monomer or oligomer. The monomer or oligomer may penetrate into the surface of the second insulating layer in a range of about 1% to about 30% in the thickness direction.

In some embodiments, a difference between elongation rates of the first insulating layer and the second insulating layer may be in a range of about 25% to about 100%.

In some embodiments, the stretchable insulating film may have each elongation rate of about 10% to about 100% in all directions.

In some embodiments, a thickness of the first insulating layer may be in the range of about 100 nm to about 1000 nm, a thickness of the second insulating layer may be in the range of about 10 nm to about 200 nm, and a thickness ratio of the first insulating layer and the second insulating layer may range from about 95:5 to about 65:35.

In some embodiments, stretchable insulating film may further include a self-assembled monolayer on the second insulating layer.

According to some example embodiments, a method of manufacturing a stretchable insulating film may include forming a first insulating layer by coating a composition including an elastomer or depositing the elastomer; and forming a second insulating layer including a cyclic siloxane polymer, the forming the second insulating layer including injecting a cyclic siloxane monomer and an initiator on the first insulating layer into a reactor equipped with a heat source and performing a polymerization reaction by low-temperature vapor deposition.

According to some example embodiments, an electronic device including the stretchable insulating film is provided.

In some embodiments, the electronic device may include a photoelectric device, a light emitting device, a sensor, a thin film transistor, or an attachable device.

The stretchable insulating film may have improved or excellent stretchability and insulating properties and can be usefully applied as an insulating film or dielectric film in electronic devices.

### BRIEF DESCRIPTION OF THE DRAWINGS

FIGS. 1 to 4 are cross-sectional views each showing thin film transistors according to some example embodiments.

FIG. 5 is a schematic plan view of a thin film transistor array panel according to some example embodiments.

FIGS. 6 to 12 are graphs (transfer curves) showing the electrical properties of the thin film transistors according to Example 7A, Example 11A, Example 12A, Example 7B, Example 11B, Example 12B, and Comparative Example 2, respectively.

FIGS. 13A and 13B are graphs showing the results of evaluating electrical properties according to stretching of the thin film transistor according to Example 12A.

FIGS. 14A and 14B are graphs showing the results of evaluating electrical properties of the thin film transistor according to Example 12A after repeated stretching.

### DETAILED DESCRIPTION

Hereinafter, embodiments are described in detail so that those skilled in the art can easily implement them. However, the actual applied structure may be implemented in various different forms and is not limited to the implementations described herein.

In the drawings, the thickness of layers, films, panels, regions, etc., are exaggerated for clarity.

It will be understood that when an element such as a layer, film, region, or substrate is referred to as being “on” another element, it may be directly on the other element or intervening elements may also be present. In contrast, when an element is referred to as being “directly on” another element, there are no intervening elements present.

Hereinafter, the terms “lower” and “upper” are used for better understanding and ease of description, but do not limit the location relationship.

As used herein, “at least one of A, B, or C,” “one of A, B, C, or any combination thereof” and “one of A, B, C, and any combination thereof” refer to each constituent element, and any combination thereof (e.g., A; B; C; A and B; A and C; B and C; or A, B, and C).

As used herein, when a definition is not otherwise provided, “substituted” refers to replacement of hydrogen of a compound by a substituent selected from a halogen, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heterocyclic group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or any combination thereof.

As used herein, when a definition is not otherwise provided, “hetero” refers to one including 1 to 4 heteroatoms selected from N, O, S, Se, Te, Si, and P.

As used herein, when a definition is not otherwise provided, “alkyl group” may be a monovalent linear or branched saturated hydrocarbon group, (e.g., a methyl group, an ethyl group, a propyl group, an isobutyl group, a sec-butyl group, a tert-butyl group, a pentyl group, an iso-amyl group, a hexyl group, and the like).

As used herein, when a definition is not otherwise provided, “alkenyl group” refers to a linear or branched monovalent hydrocarbon group having one or more carbon-carbon double bonds.

As used herein, when a definition is not otherwise provided, “alkynyl group” refers to a linear or branched monovalent hydrocarbon group having one or more carbon-carbon triple bonds.

As used herein, when a definition is not otherwise provided, “aryl group” refers to a monovalent functional group formed by the removal of one hydrogen atom from one or more rings of an arene, e.g., phenyl or naphthyl. The arene refers to a hydrocarbon having an aromatic ring, and includes monocyclic and polycyclic hydrocarbons wherein the additional ring(s) of the polycyclic hydrocarbon may be aromatic or nonaromatic.

As used herein, when a definition is not otherwise provided, “heteroaryl group” or “heterocycloalkyl group” includes at least one heteroatom such as N, O, S, Se, Te, Si, and P in the ring of the aryl group or cycloalkyl group and the remainder may be carbon. If the “heteroaryl group” or “heterocycloalkyl group” is a fused ring, the entire ring or at least one of the rings may include a heteroatom.

It will further be understood that when an element is referred to as being “on” another element, it may be above or beneath or adjacent (e.g., horizontally adjacent) to the other element. It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%). Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%). It will be understood that elements and/or properties thereof may be recited herein as being “identical” to, “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. It will be understood that elements and/or properties thereof described herein as being the “substantially” the same and/or identical encompasses elements and/or properties thereof that have a relative difference in magnitude that is equal to or less than 10%.

Further, regardless of whether elements and/or properties thereof are modified as “substantially,” it will be understood that these elements and/or properties thereof should be construed as including a manufacturing or operational tolerance (e.g., ±10%) around the stated elements and/or properties thereof. When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

Hereinafter, a stretchable insulating film according to some example embodiments will be described.

The stretchable insulating film according to some example embodiments includes a first insulating layer having stretchability and a second insulating layer on the first layer and having non-stretchability, wherein the first insulating layer includes an elastomer and the second insulating layer includes a cyclic siloxane polymer framework.

The elastomer may include an organic elastomer, an organic-inorganic elastomer, or any combination thereof.

The may include, for example, at least one of: a substituted or unsubstituted polyorganosiloxane such as polydimethylsiloxane; an elastomer having a substituted or unsubstituted butadiene moiety such as styrene-ethylene-butylene-styrene (SEBS), styrene-ethylene-propylene-styrene (SEPS), styrene-butadiene-styrene (SBS), styrene-isoprene-styrene (SIS), or styrene-isobutylene-styrene (SIBS); an elastomer having an urethane moiety; an elastomer having an acrylic moiety; an elastomer having an ester moiety; an elastomer including an amide moiety; an elastomer including an olefin moiety; or any combination thereof, but is not limited thereto.

The first insulating layer may include the elastomer having the ester moiety and the elastomer having the ester moiety may include a polymer prepared by polymerizing an acrylic monomer represented by Chemical Formula 1A.

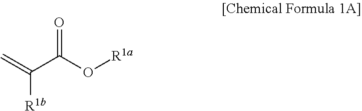

In Chemical Formula 1A, R^{1a} may be a substituted or unsubstituted C1 to C20 alkyl group, a substituted or unsubstituted C2 to C20 alkenyl group, or a substituted or unsubstituted C2 to C20 alkynyl group, and

R^{1b} may be hydrogen or a C1 to C6 alkyl group.

In the substituted or unsubstituted C1 to C20 alkyl group, the substituted or unsubstituted C2 to C20 alkenyl group, or the substituted or unsubstituted C2 to C20 alkynyl group of R^{1a} in Chemical Formula 1A, at least one methylene (—CH₂—) group may be replaced by ether (—O—), sulfide (—S—), sulfonyl (—S(═O)₂—), carbonyl (—C(═O)—), sulfoxide (—S(═O)—), ester (—C(═O)O—), amide (—C(═O)NR—) (wherein R is hydrogen, a C1 to C10 linear or branched alkyl group, or a C2 to C10 linear or branched alkenyl group), imine (—NR—) (wherein R is hydrogen, a C1 to C10 linear or branched alkyl group, or a C2 to C10 linear or branched alkenyl group), phosphate (—P(═O)(OR)O₂—) (wherein R is hydrogen, a C1 to C10 linear or branched alkyl group, or a C2 to C10 linear or branched alkenyl group), or any combination thereof.

In Chemical Formula 1A, R^{1a} may be a substituted or unsubstituted C8 to C20 linear or branched alkyl group, a substituted or unsubstituted C8 to C20 linear or branched alkenyl group, or a substituted or unsubstituted C8 to C20 linear or branched alkynyl group.

In Chemical Formula 1A, R^{1a} may be a C1 to C20 linear or branched alkyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof; a C2 to C20 linear or branched cyanoalkenyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof; or a C2 to C20 linear or branched cyanoalkynyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof.

Examples of the acrylic monomer of Chemical Formula 1A include monomers listed in Group 1, but are not limited thereto.

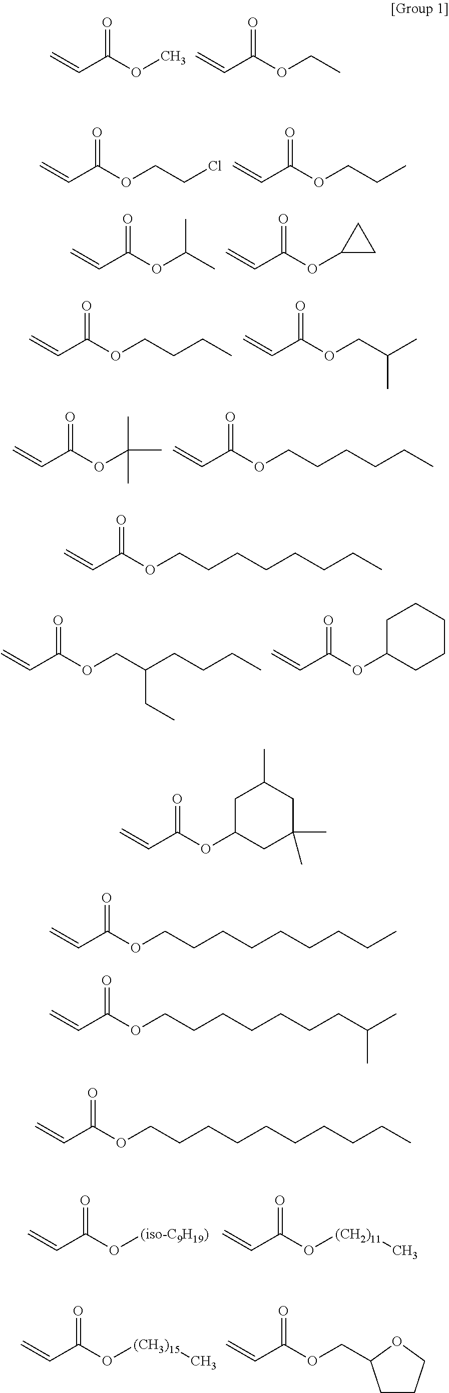

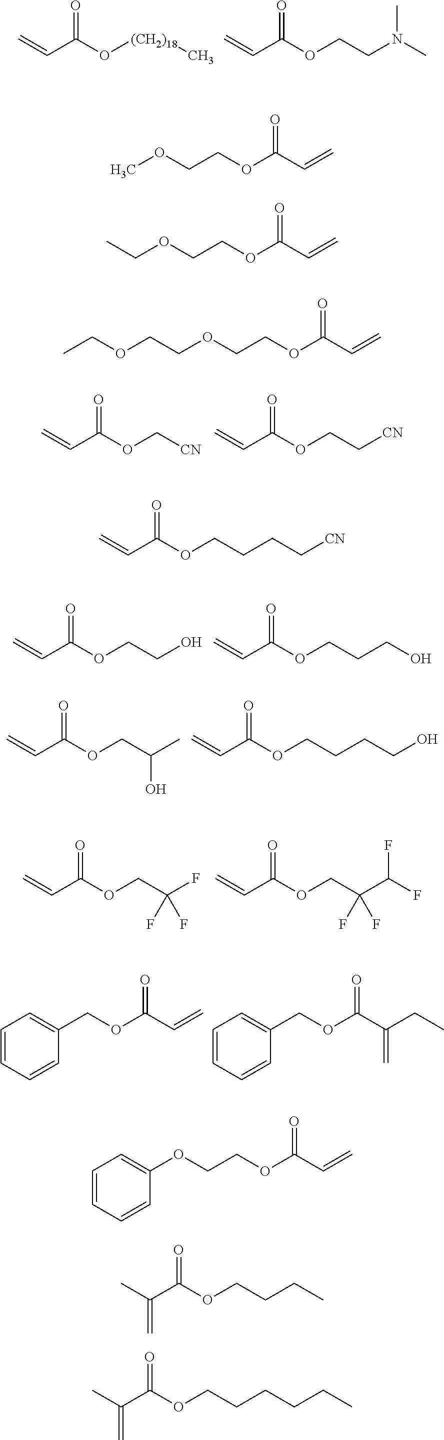

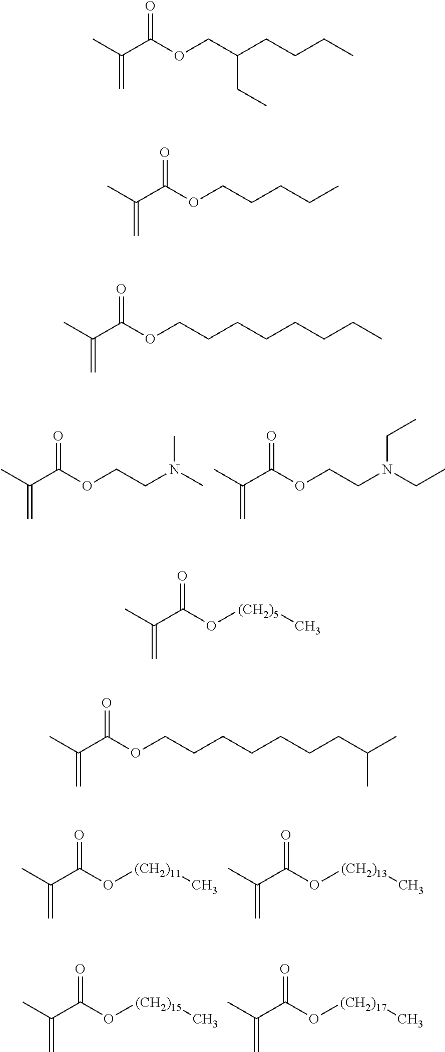

The elastomer having the ester moiety may be a polymer prepared by copolymerizing the acrylic monomer represented by Chemical Formula 1A and an alkenyl group-containing monomer.

The alkenyl group-containing monomer may be a compound represented by Chemical Formula 2A or 2B.

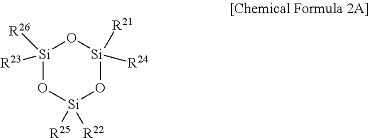

In Chemical Formula 2A,

R²¹ to R²⁶ are each independently hydrogen, a substituted or unsubstituted C1 to C20 linear or branched alkyl group or a substituted or unsubstituted C2 to C20 alkenyl group, provided at least one of R²¹ to R²⁶ is a substituted or unsubstituted C2 to C20 alkenyl group.

In some example embodiments, R²¹ to R²³ may be a substituted or unsubstituted C2 to C20 alkenyl group.

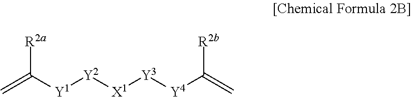

In Chemical Formula 2B,
X¹ may be —O—, —(CR^{x}R^{y})ₙ₁— (wherein R^{x} and R^{y} are each independently hydrogen or a substituted or unsubstituted C1 to C20 alkyl group, and n1 is an integer of 1 to 20), a C4 to C10 cycloalkylene group, a C3 to C10 heterocycloalkylene group, a C6 to C10 arylene group, a C3 to C10 heteroarylene group, or phosphate (—P(=O)(OR)O₂—) (wherein R is hydrogen, a C1 to C10 linear or branched alkyl group, or a C2 to C10 linear or branched alkenyl group),
Y¹ to Y⁴ may each independently be ether (—O—), carbonyl (—C(═O)—), ester (—C(═O)O—), or —(CR^{x}R^{y})ₙ₂— (wherein R^{x} and R^{y} are each independently hydrogen or a substituted or unsubstituted C1 to C20 alkyl group, and n2 is an integer of 1 to 20), and
R^{2a} and R^{2b} may each independently be hydrogen or a C1 to C6 alkyl group.

In Chemical Formula 2B, when n1 or n2 is 3 or more and 20 or less, at least one CR^{x}R^{y} that is not adjacent to each other may be replaced by ether (—O—), sulfide (—S—), sulfonyl (—S(═O)₂—), carbonyl (—C(═O)—), sulfoxide (—S(═O)—), ester (—C(═O)O—), amide (—C(═O)NR—) (wherein R is hydrogen, a C1 to C10 linear or branched alkyl group, or a C2 to C10 linear or branched alkenyl group), imine (—NR—) (wherein R is hydrogen, a C1 to C10 linear or branched alkyl group, or a C2 to C10 linear or branched alkenyl group), phosphate (—P(═O)(OR)O₂—) (wherein R is hydrogen, a C1 to C10 linear or branched alkyl group, or a C2 to C10 linear or branched alkenyl group), or any combination thereof.

For example, the alkenyl group-containing monomer of Chemical Formula 2A or 2B may include monomers listed in Group 2, but is not limited thereto.

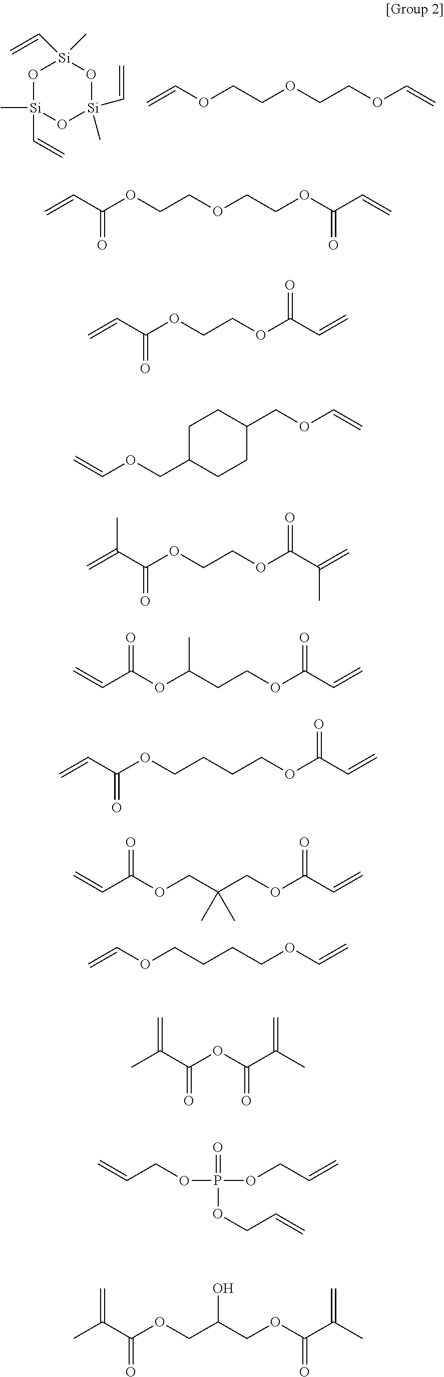

The alkenyl group-containing monomer represented by Chemical Formula 2A or 2B may be used in an amount of about 5 parts by mole to about 50 parts by mole, for example greater than or equal to about 6 parts by mole, greater than or equal to about 7 parts by mole, greater than or equal to about 8 parts by mole, greater than or equal to about 9 parts by mole, or greater than or equal to about 10 parts by mole, and less than or equal to about 49 parts by mole, less than or equal to about 45 parts by mole, less than or equal to about 40 parts by mole, less than or equal to about 35 parts by mole, less than or equal to about 30 parts by mole, less than or equal to about 25 parts by mole, or less than or equal to about 20 parts by mole, based on 100 parts by mole of the acrylic monomer represented by Chemical Formula 1A. Within the above range, it is easy to control the stretchability and insulating properties of the first insulating layer.

The elastomer having the ester moiety can be prepared by polymerizing dicarboxylic acid monomer and diol monomer. Examples of the dicarboxylic acid monomer may include an aliphatic dicarboxylic acid monomer selected from adipic acid, succinic acid, sebacic acid, undecane dioic acid, dodecane dioic acid, and a salt thereof, and the diol-based monomer may include 1,4-butanediol, 1,2-ethanediol, or 1,3-propanediol.

In some example embodiments, the elastomer having the ester moiety may be prepared by polymerizing an aliphatic dicarboxylic acid monomer and an aromatic dicarboxylic acid monomer with a diol monomer. For example, an aliphatic dicarboxylic acid monomer selected from adipic acid, succinic acid, sebacic acid, undecane dioic acid, dodecane dioic acid, and a salt thereof, an aromatic dicarboxylic acid monomer selected from phthalic acid, terephthalic acid and naphthalenedicarboxylic acid, and a diol monomer may be polymerized.

Such an elastomer having the ester moiety may be poly(butylene adipate-co-terephthalate), which is prepared by polymerizing adipic acid, terephthalic acid, and 1,4-butanediol.

The cyclic siloxane polymer included in the second insulating layer may include a structural unit represented by Chemical Formula 3.

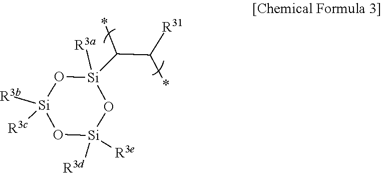

In Chemical Formula 3,
R^{3a} to R^{3e} may each independently be hydrogen, a substituted or unsubstituted C1 to C20 alkyl group, a substituted or unsubstituted C2 to C20 alkenyl group, a substituted or unsubstituted C6 to C20 aryl group, a substituted or unsubstituted C3 to C20 heteroaryl group, a substituted or unsubstituted C3 to C20 cycloalkyl group, or a substituted or unsubstituted C3 to C20 heterocycloalkyl group, and
R³¹ may be hydrogen or a C1 to C6 alkyl group (e.g., methyl group).

In Chemical Formula 3, at least one of R^{3b} and R^{3d} may be a group linking Si with the polymer main chain. Such a structure may be represented by Chemical Formula 3′.

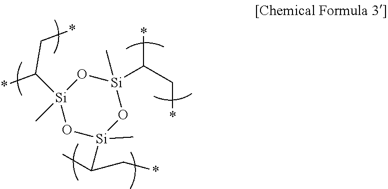

At the interface of the first insulating layer and the second insulating layer, the cyclic siloxane polymer may form a structure partially penetrating into the elastomer. As described later, the second insulating layer is formed by low-temperature vapor deposition while injecting a monomer and an initiator, so that the cyclic siloxane polymer may diffuse in the form of a monomer or oligomer into the micropores of the first insulating layer to be in an intermixing state. The monomer or oligomer may be penetrated in an amount of about 1% to about 30%, for example greater than or equal to about 2%, greater than or equal to about 3%, greater than or equal to about 4%, or greater than or equal to about 5% and less than or equal to about 25% or less than or equal to about 20% in the thickness direction from the surface of the second insulating layer. Accordingly, even if the second insulating layer is non-stretchable, the double-layer insulating film can be stretchable. That is, even if a hard second insulating layer is formed on the soft first insulating layer, sufficient stretchability can be secured.

The first insulating layer has stretchability and the second insulating layer has non-stretchability. A difference (E₁-E₂) between the elongation rate (E₁) of the first insulating layer and the elongation rate (E₂) of the second insulating layer may be in the range of about 25 to about 100%, for example greater than or equal to about 30%, greater than or equal to about 35%, greater than or equal to about 40%, or greater than or equal to about 45%, and less than or equal to about 95%, less than or equal to about 90%, less than or equal to about 85%, or less than or equal to about 80%. Herein, the elongation rate may be a percentage change in length extended up to the breaking point with respect to the initial length of the first insulating layer or the second insulating layer in the film state. Despite this difference in the elongation rates, a double-layer insulating film including the first insulating layer and the second insulating layer may have stretchability.

In some example embodiments, the stretchable insulating film may have each elongation rate of greater than or equal to about 10% in all directions. In some example embodiments, the stretchable insulating film may have each elongation rate of greater than or equal to about 10%, for example greater than or equal to about 15%, for example greater than or equal to about 20%, greater than or equal to about 25%, or greater than or equal to about 30%, and less than or equal to about 100%, for example less than or equal to about 95%, less than or equal to about 90%, less than or equal to about 85%, or less than or equal to about 80%. For example, the stretchable insulating film may have each elongation rate of about 10% to about 100%, about 10% to about 95%, about 10% to about 90%, about 10% to about 85%, about 10% to about 80%, 20% to about 100%, about 20% to about 95%, about 20% to about 90%, 20% to about 85%, or about 20% to about 80%. Herein, elongation may be a percentage change in length from the initial length to the breaking point.

An elastic modulus of the stretchable insulating film may be, for example, less than about 107 Pa, and within the above range, for example, it may be greater than or equal to about 10 Pa and less than about 107 Pa.

The stretchable insulating film has improved or excellent stretchability and insulating properties and can be formed as a uniform thin film, so that it can be formed to have a thickness within a desired range. A thickness of the first insulating layer may range from about 100 nm to about 1000 nm, for example, greater than or equal to about 110 nm, greater than or equal to about 120 nm, greater than or equal to about 130 nm, greater than or equal to about 140 nm, greater than or equal to about 150 nm, about 160 nm, about 170 nm, about 180 nm, about 190 nm, greater than or equal to about 200 nm, greater than or equal to about 210 nm, greater than or equal to about 220 nm, greater than or equal to about 230 nm, greater than or equal to about 240 nm, or greater than or equal to about 250 nm, and less than or equal to about 990 nm, less than or equal to about 980 nm, less than or equal to about 970 nm, less than or equal to about 960 nm, less than or equal to about 950 nm, less than or equal to about 940 nm, less than or equal to about 930 nm, less than or equal to about 920 nm, less than or equal to about 910 nm, less than or equal to about 900 nm, or less than or equal to about 850 nm, but is not limited thereto. Within the above range, the stretchability and insulating properties of the insulating film can be easily adjusted.

A thickness of the second insulating layer may range from about 10 nm to about 200 nm, for example, greater than or equal to about 11 nm, greater than or equal to about 12 nm, greater than or equal to about 13 nm, greater than or equal to about 14 nm, greater than or equal to about 15 nm, about 16 nm, about 17 nm, about 18 nm, about 19 nm, greater than or equal to about 20 nm, greater than or equal to about 21 nm, greater than or equal to about 22 nm, greater than or equal to about 23 nm, greater than or equal to about 24 nm, or greater than or equal to about 25 nm, and less than or equal to about 190 nm, less than or equal to about 180 nm, less than or equal to about 170 nm, less than or equal to about 160 nm, less than or equal to about 150 nm, less than or equal to about 140 nm, less than or equal to about 130 nm, less than or equal to about 120 nm, less than or equal to about 110 nm, less than or equal to about 100 nm, or less than or equal to about 85 nm, but is not limited thereto. Within the above range, the stretchability and insulating properties of the insulating film can be easily adjusted.

A thickness ratio of the first insulating layer and the second insulating layer may be in the range of about 95:5 to about 65:35, for example, about 80:20 to about 90:10. That is, the thickness of the second insulating layer may be in the range of about 5% to about 35%, for example, about 10% to about 20% of the total thickness of the insulating film. Within the above range, the thickness of the second insulating layer may be greater than or equal to about 5%, greater than or equal to about 10%, greater than or equal to about 15%, greater than or equal to about 20%, or greater than or equal to about 30% and less than or equal to about 35% or less than or equal to about 33%. Within the above range, the stretchability and insulating properties of the insulating film can be easily adjusted.

Since the second insulating layer has a siloxane structure (Si—O—Si), hydroxylation of the surface of the second insulating layer is induced by oxygen plasma, acid treatment, ultraviolet ozone treatment, etc., in an appropriate moisture environment, and then a silane compound is coated and heat treated to form a self-assembled monolayer can be easily formed. Accordingly, the stretchable insulating film may further include a self-assembled monolayer on the second insulating layer.

For example, the self-assembled monolayer may be introduced onto the second insulating layer through a process of treating the surface of the second insulating layer with oxygen plasma; coating it with a solution including a silane compound dissolved in a hydrocarbon solvent (e.g., n-hexane), for example dipping in a solution (e.g., about 1 minute to about 60 minutes); washing with a carbon-hydrogen solvent (e.g., n-hexane); and then performing heat treatment (for example, heat treatment at about 100° C. to about 120° C.).

The silane compound may be halosilane, alkoxysilane, and the like. Examples of the halosilane or alkoxy silane may be octadecyltrichlorosilane (ODTS), octyltrichlorosilane (OTS), octadecyltrimethoxysilane (ODTMS), octyl trimethoxy silane (OTMS), and the like. The coating of the silane compound solution may be performed by spin coating, slit coating, inkjet coating, nozzle printing, spraying, dropping, dipping, and/or doctor blade coating.

According to some example embodiments, a method of manufacturing a stretchable insulating film includes
coating a composition including an elastomer or depositing an elastomer to form a first insulating layer, and
injecting a cyclic siloxane monomer and an initiator on the first insulating layer into a reactor equipped with a heat source and performing a polymerization reaction by low-temperature vapor deposition, to form a second insulating layer including a cyclic siloxane polymer. The heat source may include an electric heating circuit or a heat lamp.

The elastomer is the same as described above.

The first insulating layer may be formed by coating a composition in which an elastomer is dissolved in a solvent and then heat treating it. The solvent may be chlorobenzene, toluene, dodecane, hexane, 1,2,3,4-tetrahydronaphthalene, 2-propanol, ethoxynonafluorobutane, etc., but is not limited thereto. The composition may further include a crosslinking agent, such as an azide crosslinking agent. In this case, a dense first insulating layer with high density can be provided.

The coating of the composition may be performed by, for example, spin coating, slit coating, inkjet coating, nozzle printing, spraying, dropping, dipping and/or doctor blade coating, but is not limited thereto.

The heat treatment may be performed, for example, at a temperature of about 50° C. to about 200° C., for about 1 minute to about 10 hours, but is not limited thereto. UV irradiation, etc. may be performed before the heat treatment.

In addition, the first insulating layer may be manufactured by iCVD (initiated chemical vapor deposition, initiated CVD), which includes a process of vapor deposition at a low temperature (about 10° C. to about 50° C., for example, about 25° C. to about 38° C.) while injecting the monomer constituting the elastomer and an initiator.

The monomer constituting the elastomer may include a monomer represented by Chemical Formula 1A and optionally a monomer represented by Chemical Formula 2A or 2B.

The initiator may be a peroxide compound, a benzophenone compound, and the like. The peroxide compound may include dicumyl peroxide, benzoyl peroxide, lauryl peroxide, di-tert-butyl peroxide, t-butyl cumyl peroxide, di(tert-butyl peroxy isopropyl) benzene, 2,5-dimethyl-2,5-di(t-butyl peroxy)hexane, 2-butanone peroxide, and the like.

In the iCVD process, the monomer and the initiator can be introduced into a reactor with a heat source installed at the top to polymerize the monomer on the substrate. The heat source may be a filament array, but is not limited thereto. The temperature of the heat source may be maintained to be greater than or equal to about 150° C., or greater than or equal to about 200° C. and less than or equal to about 350° C.

At this time, the temperature of the substrate located away from the heat source can be maintained as low as about 10° C. to about 50° C., for example, about 25° C. to about 38° C., so that damage can be reduced even if a substrate that is weak to heat is used. The polymerization reaction can be performed for about 10 minutes to about 60 minutes while maintaining the pressure in the reactor at about 50 mTorr to about 1000 mTorr or about 200 mTorr to about 400 mTorr, and thus high vacuum equipment is not required. When forming the first insulating layer using the iCVD process as described above, a uniform thin film can be formed without causing any damage to the underlying film compared to the conventional deposition process (PECVD or CVD).

The second insulating layer can be manufactured by the iCVD process, which includes a process of vapor deposition at low temperature while injecting the cyclic siloxane monomer and the initiator onto the first insulating layer formed in the same manner as above.

The cyclic siloxane monomer may be represented by Chemical Formula 3A.

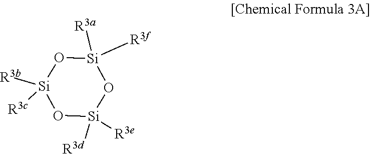

In Chemical Formula 3A,

R^{3a} to R^{3e} are each independently hydrogen, a substituted or unsubstituted C1 to C20 alkyl group, a substituted or unsubstituted C2 to C20 alkenyl group, a substituted or unsubstituted C6 to C20 aryl group, a substituted or unsubstituted C3 to C20 heteroaryl group, a substituted or unsubstituted C3 to C20 cycloalkyl group, or a substituted or unsubstituted C3 to C20 heterocycloalkyl group, provided that at least one of R^{3a} to R^{3e} is a substituted or unsubstituted C2 to C20 alkenyl group.

The initiator is as described above, and the iCVD process is also as described above.

When forming the second insulating layer using the iCVD process as described above, damage to the lower film due to solvent can be prevented compared to the solution process, and a uniform thin film can be formed without causing damage to the underlying film due to heat compared to the conventional deposition process (PECVD or CVD).

The stretchable insulating film has improved or excellent stretchability and insulating properties and can be usefully applied to electronic devices that require such properties. In particular, when applied to electronic devices, the electrical properties of the electronic devices can be stably maintained even after stretching or repeated stretching under high strain.

The electronic device may be, for example, a thin film transistor, a photoelectric device, a light emitting device, a sensor, or an attachable device (biological sensor).

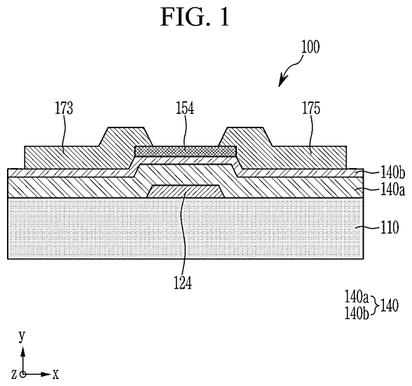

Hereinafter, an example of a thin film transistor including the stretchable insulating film described above will be described with reference to FIGS. 1 to 4.

FIGS. 1 to 4 are cross-sectional views each showing thin film transistors according to some example embodiments.

Referring to FIGS. 1 to 4, thin film transistors 100, 100a. 200, and 200a according to some example embodiments include a gate electrode 124, an organic semiconductor layer 154 overlapping the gate electrode 124, and a gate insulating film 140 between a gate electrode 124 and the organic semiconductor layer 154, and a source electrode 173 and a drain electrode 175 that are electrically connected to the organic semiconductor layer 154.

The thin film transistors 100, 100a. 200, and 200a have a bottom gate structure, a top gate structure, a bottom contact structure, or a top contact structure depending on the position of the gate electrode 124 and/or the channel position of the organic semiconductor layer 154, and may be variously implemented by combining them.

First, referring to FIG. 1, the thin film transistor 100 according to some example embodiments may be a thin film transistor with a bottom gate and top contact structure. Specifically, the thin film transistor 100 according to some example embodiments includes a gate electrode 124 on a substrate 110; a gate insulating film 140 on the gate electrode 124; an organic semiconductor layer 154 on the gate insulating film 140; and a source electrode 173 and a drain electrode 175 that are electrically connected to the organic semiconductor layer 154.

The substrate 110 may be a support substrate supporting the thin film transistor 100, for example, a glass substrate, a polymer substrate, or a silicon wafer. The polymer substrate may include, for example, polyethylene terephthalate, polyethylene naphthalate, polycarbonate, polyacrylate, polyimide, or any combination thereof, but is not limited thereto.

For example, the substrate 110 may be a stretchable substrate that can be stretched in a desired and/or alternatively predetermined direction and can be restored again. The stretchable substrate may flexibly respond to external forces or external movements such as twisting, pressing, and pulling in a desired and/or alternatively predetermined direction. The stretchable substrate may include a stretchable material, and the stretchable material may include an organic elastomer, an organic-inorganic elastomer, an inorganic elastomer-like material, or any combination thereof. The organic elastomer or the organic-inorganic elastomer may include, for example, a substituted or unsubstituted polyorganosiloxane such as polydimethylsiloxane; an elastomer having a substituted or unsubstituted butadiene moiety such as styrene-ethylene-butylene-styrene, an elastomer having an urethane moiety, an elastomer having an acrylic moiety, an elastomer having an ester moiety, an elastomer including an amide moiety, olefin moiety, or any combination thereof, but is not limited thereto. The inorganic elastomer-like material may include, but is not limited to, a ceramic having elasticity, a solid metal, a liquid metal, or any combination thereof.

The substrate 110 may have one layer or two or more layers made of different materials.

A gate electrode 124 is formed on the substrate 110. The gate electrode 124 is connected to a gate line (not shown) that transmits the gate signal. The gate electrode 124 may be made of, for example, gold (Au), copper (Cu), nickel (Ni), aluminum (Al), molybdenum (Mo), chromium (Cr), tantalum (Ta), titanium (Ti), an alloy thereof, or any combination thereof, but is not limited thereto. However, when the substrate 110 is a silicon wafer, the gate electrode 124 may be a doped region of the silicon wafer. The gate electrode 124 may have one layer or two or more layers.

A gate insulating film 140 is formed on the gate electrode 124. The gate insulating film 140 may include a first insulating layer 140a and a second insulating layer 140b. The gate insulating film 140 including the first insulating layer 140a and the second insulating layer 140b may be the aforementioned stretchable insulating film. The first insulating layer 140a may be in contact with the gate electrode 124, and the second insulating layer 140b may be in contact with the organic semiconductor layer 154.

An organic semiconductor layer 154 is formed on the gate insulating film 140. The organic semiconductor layer 154 may include an organic semiconductor. The organic semiconductor material may include a low-molecular semiconductor material, a polymeric semiconductor material, or any combination thereof. The organic semiconductor layer 154 may further include an elastomer. The elastomer may provide stretchability to the organic semiconductor layer 154, and may include for example polydimethylsiloxane (PDMS), styrene-ethylene-butylene-styrene (SEBS), styrene-ethylene-propylene-styrene (SEPS), styrene-butadiene-styrene (SBS), styrene-isoprene-styrene (SIS), styrene-isobutylene-styrene (SIBS), or any combination thereof, but is not limited thereto. In this way, the organic semiconductor layer 154 can implement a stretchable organic semiconductor layer by including an elastomer.

The organic semiconductor layer 154 may be formed by preparing an organic semiconductor in solution form and coating it by a solution process such as spin coating, slit coating, inkjet coating, nozzle printing, spraying, dropping, dipping and/or doctor blade coating. Additionally, the organic semiconductor layer 154 may be formed by vacuum deposition or thermal deposition of an organic semiconductor.

A source electrode 173 and a drain electrode 175 are formed on the organic semiconductor layer 154. The source electrode 173 and the drain electrode 175 face each other on the organic semiconductor layer 154 with the gate electrode 124 at the center. The source electrode 173 is connected to a data line (not shown) that transmits a data signal. The source electrode 173 and the drain electrode 175 may be made of gold (Au), copper (Cu), nickel (Ni), aluminum (Al), molybdenum (Mo), chromium (Cr), tantalum (Ta), titanium (Ti), an alloy thereof, or any combination thereof, but are not limited thereto.

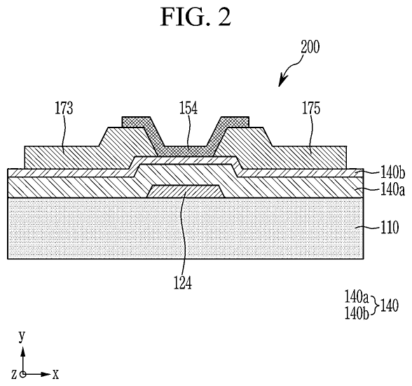

Referring to FIG. 2, the thin film transistor 200 according to some example embodiments may be a thin film transistor with a bottom gate and bottom contact structure, unlike the aforementioned embodiment. For example, the thin film transistor 200 according to some example embodiments includes an organic semiconductor layer 154 on a substrate 110; a source electrode 173 and a drain electrode 175 electrically connected to the organic semiconductor layer 154; a gate insulating film 140 on the organic semiconductor layer 154, the source electrode 173, and the drain electrode 175; and a gate electrode 124 formed on the gate insulating film 140. The gate electrode 140 includes a first insulating layer 140a and a second insulating layer 140b. The gate insulating film 140 including the first insulating layer 140a and the second insulating layer 140b may be the aforementioned stretchable insulating film. The first insulating layer 140a may be in contact with the gate electrode 124 and the second insulating layer 140b may be in contact with the organic semiconductor layer 154.

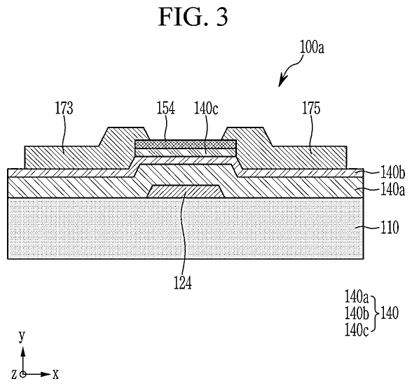

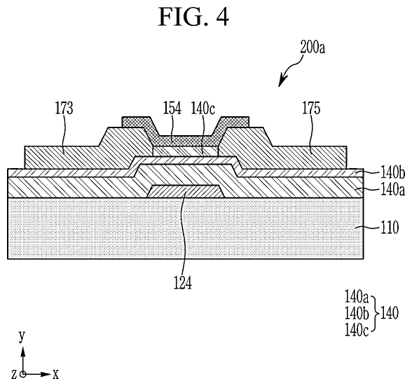

The gate insulating film 140 of the thin film transistors 100 and 200 shown in FIGS. 1 and 2 may be formed as a self-assembled monolayer on the upper portion of the second insulating layer. Thin film transistors 100a and 200a having this structure are shown in FIGS. 3 and 4.

Referring to FIG. 3, the gate insulating film 140 of the thin film transistor 100 having the bottom gate and top contact structure of FIG. 1 includes a first insulating layer 140a, a second insulating layer 140b, and a self-assembled monolayer 140c.

Referring to FIG. 4, the gate insulating film 140 of the thin film transistor 200 of the bottom gate and bottom contact structure of FIG. 2 includes a first insulating layer 140a, a second insulating layer 140b, and a self-assembled monolayer 140c.

In FIGS. 3 and 4, the self-assembled monolayer 140c may be partially formed in the area where the organic semiconductor layer 154 will be located on the second insulating layer 140b.

The self-assembled monolayer 140c can be formed using halosilane, alkoxysilane, etc., and specific examples of halosilane or alkoxysilane include octadecyl trichlorosilane (ODTS), octyl trichlorosilane, OTS), octadecyl trimethoxysilane (ODTMS), and octyl trimethoxysilane (OTMS).

The self-assembled monolayer 140c improves the alignment of organic semiconductor molecules, increases the packing density of the organic semiconductor layer 154, and can increase charge mobility when applied to a device.

Although examples of thin film transistors have been described here, the present disclosure is not limited thereto and can be equally applied to thin film transistors of all structures.

The thin film transistors 100, 100a. 200, and 200a) may be included in a thin film transistor array panel.

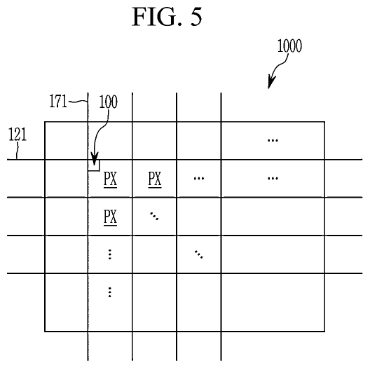

FIG. 5 is a schematic plan view of a thin film transistor array panel according to some example embodiments.

Referring to FIG. 5, the thin film transistor array panel 1000 according to some example embodiments includes a plurality of subpixels PX partitioned by a plurality of gate lines 121 and a plurality of data lines 171 and the plurality of subpixels PX may be arranged in a matrix form along rows and/or columns. Each subpixel PX may include one or more thin film transistors 100 as switching and/or driving devices. Each subpixel PX may include one or more thin film transistors 100 as switching and/or driving devices. Although FIG. 5 shows a thin film transistor array panel 1000 including the thin film transistor 100 of FIG. 1, the thin film transistors 100a, 200, and 200a shown in FIGS. 2 and 4 may also be applied in the same manner.

The thin film transistors 100, 100a. 200, 200a and the thin film transistor array panel 1000 may be applied as switching elements and/or driving elements in various electronic devices.

The thin film transistor may be applied to electronic devices such as display devices such as a bendable display panel, a foldable display panel, and a rollable display panel; wearable device; skin-like display panel, skin-like sensor; smart clothing, but is not limited to this. The display device may include, but is not limited to, a liquid crystal display device, an organic light emitting display device, a quantum dot display device, an electrophoretic display device, an organic photoelectric device, and an organic sensor.

The electronic device may be, for example, mobile phones, video phones, smart phones, mobile phones, smart pads, smart watches, digital cameras, tablet PCs, laptop PCs, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT), Internet of all things (IoE), drones, door locks, safes, automatic teller machines (ATM), security devices, medical devices, or automotive electronic components, but is not limited thereto.

Hereinafter, the embodiments are illustrated in more detail with reference to examples. However, the following examples are for illustrative purposes only and do not limit the scope of rights.

### Example 1A: Manufacturing of Stretchable Insulating Film

A first insulating layer with an average thickness of 525 nm is formed by adding 0.6 wt % of an SEBS polymer having a structural unit of Chemical Formula 1-1 (TUFTEC, Asahi Kasei Corp.) and 0.024 wt % of bis(6-((4-azido-2,3,5,6-tetrafluorobenzoyl)oxy)hexyl) decanedioate to toluene to prepare a composition, spin-coating the composition on a styrene-ethylene-butylene-styrene (SEBS) substrate at 1000 rpm, irradiating UV of 248 to 254 nm with 10,000 mJ/cm² thereinto, and heat-treating it at 130° C. for 1 hour under a nitrogen atmosphere.

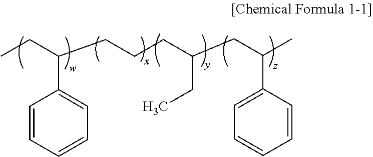

In Chemical Formula 1-1, w, x, y, and z represent a molar ratio of each structural unit, and (w+z):(x+y) is 12:88.

On the first insulating layer, a second insulating layer with a thickness of 100 nm is formed by mixing 1,3,5-trivinyl-1,3,5-trimethylcyclotrisiloxane represented by Chemical Formula 2A-1 as an initiator with di-tert-butyl peroxide (TBPO) and then, introducing the mixture into a reactor with a high temperature filament array mounted on top to proceed with polymerization at a reaction pressure of 200 mTorr. The high temperature filament array is maintained at 150° C. to 250° C.

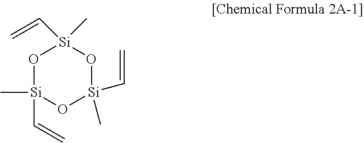

### Example 2A: Manufacturing of Stretchable Insulating Film

A stretchable insulating film is manufactured in the same manner as in Example 1A except that the first insulating layer is formed by using polybutylene adipate terephthalate (PBAT, Ecoflex™, BASF), having a structural unit represented by Chemical Formula 1-2, instead of the SEBS polymer.

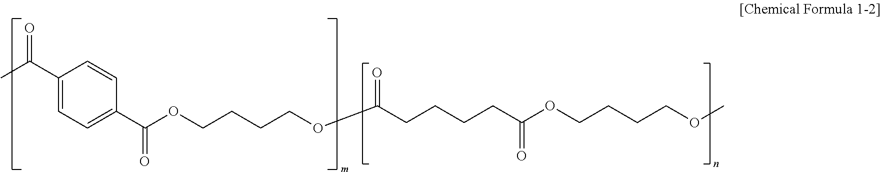

In Chemical Formula 1-2, m and n represent a molar ratio of each structural unit.

### Example 3A: Manufacturing of Stretchable Insulating Film

A stretchable insulating film is manufactured in the same manner as in Example 1A except that the first insulating layer is formed by using polydimethylsiloxane (SYLGARD™, Dow Chemical) represented by Chemical Formula 1-3 instead of the SEBS polymer.

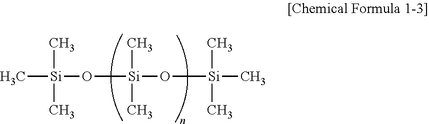

In Chemical Formula 1-3, n represents a polymerization degree.

### Example 4A: Manufacturing of Stretchable Insulating Film

A first insulating layer with an average thickness of 725 nm is formed by mixing isononyl acrylate represented by Chemical Formula 1A-1 (an acrylic monomer) and 1,3,5-trivinyl-1,3,5-trimethylcyclotrisiloxane represented by Chemical Formula 2A-1 (an alkenyl group-containing monomer) as an initiator with di-t-butyl peroxide and then, introducing the mixture into a reactor with a high temperature filament array mounted on top to proceed with polymerization at a reaction pressure of 200 mTorr. The high temperature filament array is maintained at 150° C. to 250° C.

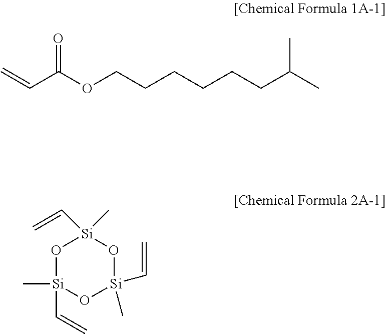

On the first insulating layer, a second insulating layer with a thickness of 100 nm thickness is formed by mixing 1,3,5-trivinyl-1,3,5-trimethylcyclotrisiloxane represented by Chemical Formula 2A-1 as an initiator with di-t-butyl peroxide and then, introducing the mixture into a reactor with a filament array mounted on top to proceed with polymerization.

### Example 5A: Manufacturing of Stretchable Insulating Film

A stretchable insulating film is manufactured in the same manner as in Example 4A except that a first insulating layer with an average thickness of 425 nm is formed by mixing 2-cyanoethyl acrylate represented by Chemical Formula 1A-2 (an acrylic monomer) as an initiator with di-t-butyl peroxide and then, introducing the mixture into a reactor with a filament array mounted on top to proceed with polymerization.

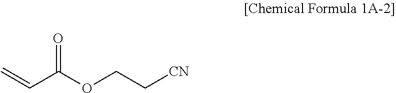

### Example 6A: Manufacturing of Stretchable Insulating Film

A stretchable insulating film is manufactured in the same manner as in Example 4A except that a first insulating layer with an average thickness of 875 nm is formed by mixing tetrahydrofurfuryl acrylate represented by Chemical Formula 1A-3 (an acrylic monomer) as an initiator with di(ethylene glycol) divinyl ether represented by Chemical Formula 2A-2 (DEGDVE, an alkenyl group-containing monomer) and then, introducing the mixture into a reactor with a filament array mounted on top to proceed with polymerization.

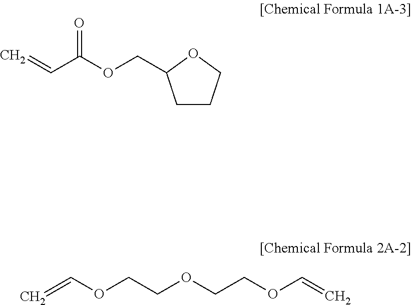

### Examples 1B to 6B: Manufacturing of Stretchable Insulating Film

Each of the stretchable insulating films according to Examples 1A to 6A is immersed in a solution, which is prepared by dissolving octadecyl trichlorosilane (ODTS) in n-hexane, for 60 minutes to additionally form a self-assembled monolayer on the second insulating layer to manufacture each stretchable insulating film according to Examples 1B to 6B.

### Comparative Example 1: Manufacturing of Stretchable Insulating Film

A SEBS stretchable insulating film (965 nm) cross-linked with an azide cross-linking agent is manufactured according to a method described in Nature, (2018) 555, pp. 83 to 88.

### Example 7A: Manufacturing of Thin Film Transistor

A gate electrode is formed by thermally depositing Au on a glass substrate that is manufactured by coating styrene-ethylene-butylene-styrene (SEBS) to be 0.5 μm thick, and then a gate insulating film is formed in the same manner as manufacturing the stretchable insulating film according to Example 1A.

Subsequently, on the gate insulating film, an organic semiconductor solution, which is prepared by mixing an organic semiconductor polymer represented by Chemical Formula A (poly(2,5-bis(2-octyldodecyl)-3,6-di(thiophen-2-yl)diketopyrrolo[3,4-c]pyrrole-1,4-dione-alt-thieno[3,2-b]thiophen), DPPT-TT, a number average molecular weight: 90,000) and SEBS in a weight ratio of 4:6 in chlorobenzene at a concentration of 0.6 wt %, is spin-coated to be 70 nm-thick at 1000 rpm and then, heat-treated at 130° C. for 1 hour under a nitrogen atmosphere to form an organic semiconductor layer.

The organic semiconductor polymer is synthesized according to Science, (2017) 355, pp. 59 to 64.

Subsequently, on the organic semiconductor layer, Au is thermally deposited to form a source electrode and a drain electrode, manufacturing a thin film transistor with a structure shown in FIG. 1.

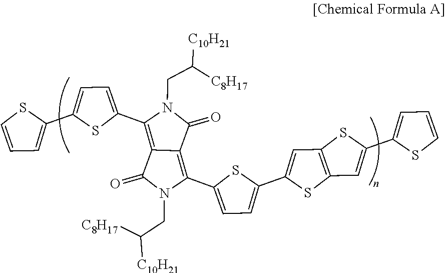

In Chemical Formula A, n represents a polymerization degree.

### Examples 8A to 12A: Manufacturing of Thin Film Transistor

A thin film transistor with a structure shown in FIG. 1 is manufactured in the same manner as in Example 7A except that each gate insulating film is formed in the same manner as the method of manufacturing the stretchable insulating films according to Examples 2A to 6A, respectively.

### Example 7B: Manufacturing of Thin Film Transistor

A gate electrode is formed by thermally depositing Au on a styrene-ethylene-butylene-styrene (SEBS) substrate, which is used to form a gate insulating film in the same manner as the method of manufacturing the stretchable insulating film according to Example 1B. Subsequently, on the gate insulating film, an organic semiconductor solution, which is prepared by mixing an organic semiconductor polymer represented by Chemical Formula A of Example 7A (poly(2,5-bis(2-octyldodecyl)-3,6-di(thiophen-2-yl)diketopyrrolo[3,4-c]pyrrole-1,4-dione-alt-thieno[3,2-b]thiophen), DPPT-TT, a number average molecular weight: 90,000) and SEBS in a weight ratio of 4:6 in chlorobenzene at a concentration of 0.6 wt %, is spin-coated to be 70 nm-thick at 1000 rpm and then, heat-treated at 130° C. for 1 hour under a nitrogen atmosphere to form an organic semiconductor layer.

The organic semiconductor polymer is synthesized according to Science, (2017) 355, pp. 59 to 64.

Subsequently, on the organic semiconductor, Au is thermally deposited to form a source electrode and a drain electrode, manufacturing a thin film transistor with a structure shown in FIG. 1.

### Examples 8B to 12B: Manufacturing of Thin Film Transistor

A thin film transistor with a structure shown in FIG. 1 is manufactured in the same manner as in Example 7B except that each gate insulating film is formed in the same manner as the method of manufacturing the stretchable insulating films according to Examples 2B to 6B, respectively.

### Comparative Example 2: Manufacturing of Thin Film Transistor

A thin film transistor with a structure shown in FIG. 1 is manufactured in the same manner as in Example 7A except that a gate insulating film is formed in the same manner as the method of manufacturing the stretchable insulating film according to Comparative Example 1.

### Evaluation I: Charge Mobility

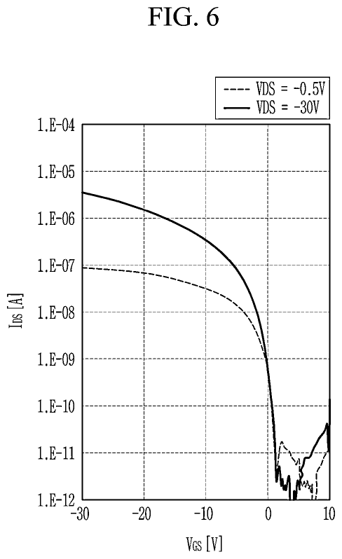

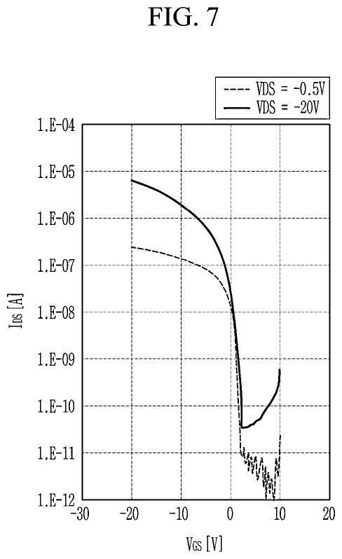

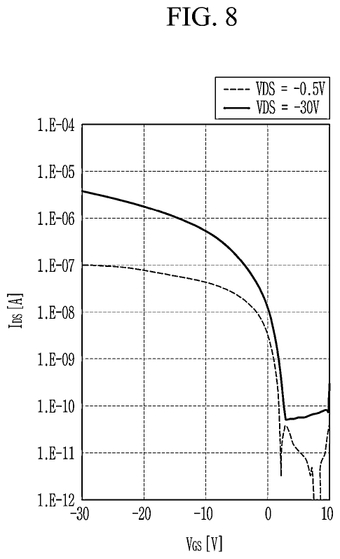

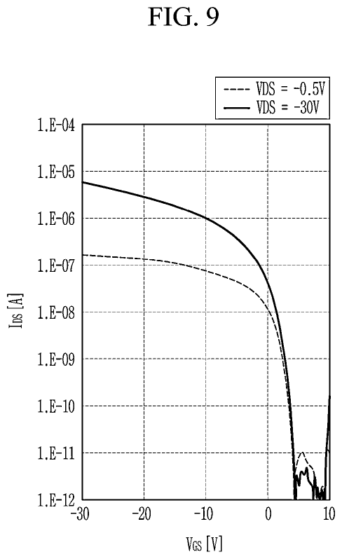

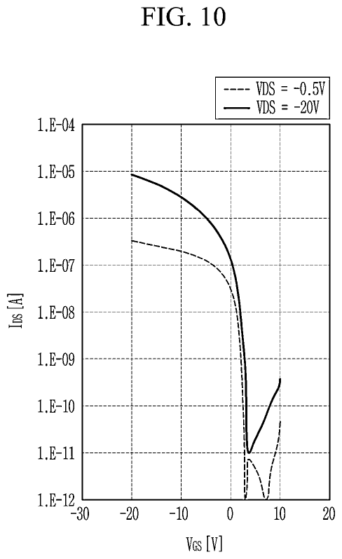

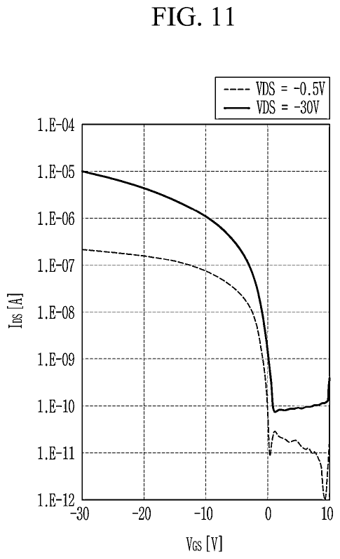

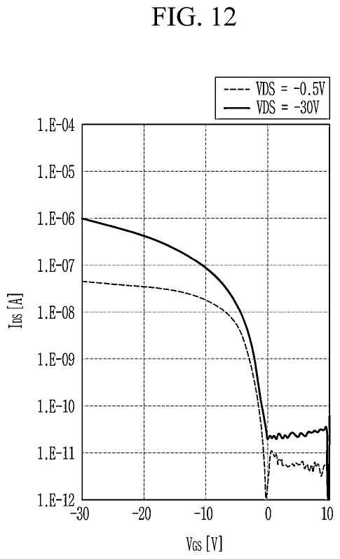

Each of the thin film transistors according to Examples 7A, 11A, 12A, 7B, 11B, and 12B and Comparative Example 2, when a gate voltage (10 V to −30 V) and a drain-source voltage (−0.5 V for linear regime, −20 V for saturation regime) are applied thereto, is evaluated with respect to electrical characteristics by using KEITHLEY 4200A-SCS. The results are respectively shown in FIGS. 6 to 10. FIGS. 6 to 10 are graphs (transfer curves) respectively showing electrical characteristics of the thin film transistors according to Examples 7A, 11A, 12A, 7B, 11B, and 12B and Comparative Example 2.

Each of the thin film transistors according to Examples 7A, 11A, 12A, 7B, 11B, and 12B and Comparative Example 2 is calculated with respect to charge mobility, and the results are shown in Table 1.

The charge mobility is calculated according to Equation 1.

$${I}_{D} = \frac{W}{L} {μ}_{FET} {C}_{l} ( {V}_{G} - {V}_{T} ) {V}_{D} \qquad [ Equation 1 ]$$

In Equation 1, μ_{FET} is charge mobility, ID is a drain current, V_{G} is a gate voltage, V_{T} is a threshold voltage, V_{SD} is a voltage potential across source-drain electrodes, Cᵢ is capacitance per unit area of a gate insulating film, W is a channel width of an organic semiconductor layer, and L is a channel length of the organic semiconductor layer.

TABLE 1

| | Charge mobility (cm²/Vs) |
|---|---|
| Example 7A | 0.26 |
| Example 11A | 0.27 |
| Example 12A | 0.24 |
| Example 7B | 0.41 |
| Example 11B | 0.50 |
| Example 12B | 0.58 |
| Comparative Example 2 | 0.17 |

Referring to the results of FIGS. 6 to 10 and Table 1, the thin film transistors according to Examples 7A, 11A, 12A, 7B, 11B, and 12B exhibit improved or excellent charge mobility, compared with that of Comparative Example 2.

### Evaluation II: Stretching Characteristics of Thin Film Transistors

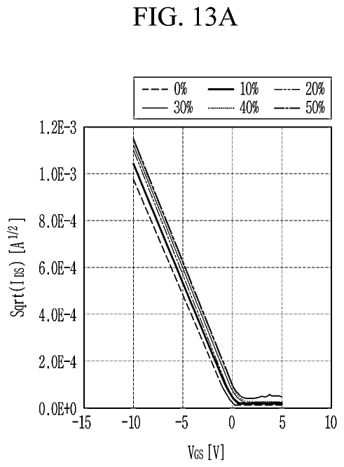

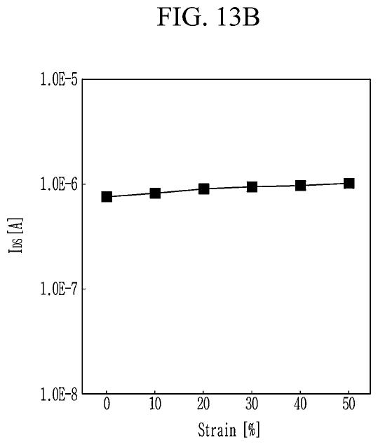

Each of the thin film transistors of the examples and the comparative examples is stretched to 10% to 50% in a channel direction to evaluate changes in the electrical characteristics. Electrical signals according to the stretching are evaluated from a current (IDS) flowing between source and drain electrodes, when a voltage ranging from 10 V to −15 V is applied between gate electrode and source electrode under a voltage condition of −10 V applied to the source and drain electrodes. The stretching results of the thin film transistor of Example 12A are shown in FIGS. 13A and 13B. FIGS. 13A and 13B are graphs showing the results of evaluating electrical characteristics according to the stretching of the thin film transistor according to Example 12A.

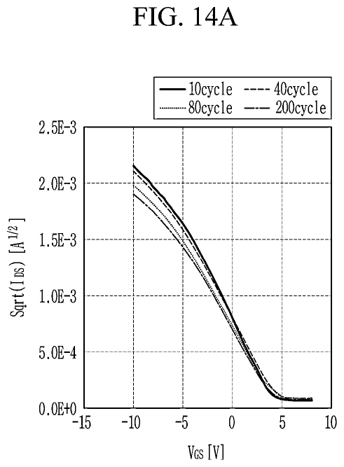

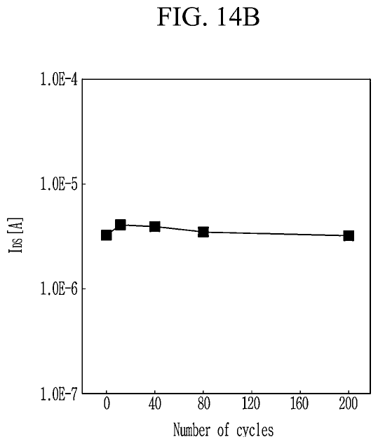

The thin film transistor according to Example 12A is 200 times repeatedly stretched under a fixed strain condition of 30% to check changes of the electrical characteristics. The results of evaluating the electrical characteristics after repeatedly stretching the thin film transistor of Example 12A are shown in FIGS. 14A and 14B. FIGS. 14A and 14B are graphs showing the result of evaluating the electrical characteristics of the thin film transistor according to Example 12A after the repeated elongation.

Referring to FIGS. 13A, 13B, 14A, and 14B, the thin film transistor according to Example 12A, even if stretched at high strain or repeatedly stretched, maintained improved or excellent electrical characteristics. Accordingly, the thin film transistor according to Example 12A exhibits improved or excellent electrical stability after the stretching and the repeated stretching.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While this disclosure has been described in connection with what is presently considered to be practical example embodiments, it is to be understood that aspects of inventive concepts are not limited to the disclosed embodiments. On the contrary, aspects of inventive concepts are intended to cover various modifications and equivalent arrangements included within the spirit and scope of the appended claims.

### DESCRIPTION OF SYMBOLS

110: substrate
124, 125: gate electrode
140: gate insulating film
140a: first insulating layer
140b: second insulating layer
154: organic semiconductor layer
173: source electrode
175: drain electrode

What is claimed is:

1. A stretchable insulating film, comprising
a first insulating layer having stretchability; and
a second insulating layer on the first layer and having non-stretchability, wherein
the first insulating layer includes an elastomer, and
the second insulating layer includes a cyclic siloxane polymer framework.

2. The stretchable insulating film of claim 1, wherein
the elastomer includes an organic elastomer, an organic-inorganic elastomer, or any combination thereof.

3. The stretchable insulating film of claim 1, wherein the elastomer includes at least one of:
a substituted or unsubstituted polyorganosiloxane;
an elastomer having a substituted or unsubstituted butadiene moiety of styrene-ethylene-butylene-styrene (SEBS), styrene-ethylene-propylene-styrene (SEPS), styrene-butadiene-styrene (SBS), styrene-isoprene-styrene (SIS), or styrene-isobutylene-styrene (SIBS); or
an elastomer including a urethane moiety, an elastomer having an acrylic moiety, an elastomer having an ester moiety, an elastomer including an amide moiety, an elastomer including an olefin moiety, or any combination thereof.

4. The stretchable insulating film of claim 3, wherein
the first insulating layer includes the elastomer having the ester moiety and the elastomer having the ester moiety includes a polymer prepared by polymerizing an acrylic monomer represented by Chemical Formula 1A: 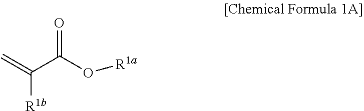
wherein, in Chemical Formula 1A,
R^{1a} is a substituted or unsubstituted C1 to C20 alkyl group, a substituted or unsubstituted C2 to C20 alkenyl group, or a substituted or unsubstituted C2 to C20 alkynyl group, and
R^{1b} is hydrogen or a C1 to C6 alkyl group.

5. The stretchable insulating film of claim 4, wherein
in the substituted or unsubstituted C1 to C20 alkyl group, the substituted or unsubstituted C2 to C20 alkenyl group, or the substituted or unsubstituted C2 to C20 alkynyl group of R^{1a} of Chemical Formula 1A, at least one methylene (—CH₂—) group is replaced by ether (—O—), sulfide (—S—), sulfonyl (—S(═O)₂—), carbonyl (—C(═O)—), sulfoxide (—S(═O)—), ester (—C(═O)O—), amide (—C(═O)NR—), wherein R is hydrogen, a C1 to C10 linear or branched alkyl group, or a C2 to C10 linear or branched alkenyl group, imine (—NR—), wherein R is hydrogen, a C1 to C10 linear or branched alkyl group, or a C2 to C10 linear or branched alkenyl group, phosphate (—P(═O)(OR)O₂—), wherein R is hydrogen, a C1 to C10 linear or branched alkyl group, or a C2 to C10 linear or branched alkenyl group, or any combination thereof.

6. The stretchable insulating film of claim 4, wherein,
in Chemical Formula 1A, R^{1a} is:
a C1 to C20 linear or branched alkyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof;
a C2 to C20 linear or branched cyanoalkenyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof; or
a C2 to C20 linear or branched cyanoalkynyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof.

7. The stretchable insulating film of claim 3, wherein
the first insulating layer includes the elastomer having the ester moiety and the elastomer having the ester moiety includes a polymer prepared by copolymerizing an acrylic monomer represented by Chemical Formula 1A and an alkenyl group-containing monomer: 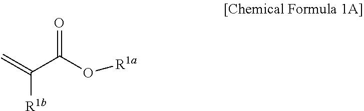
wherein, in Chemical Formula 1A,
R^{1a} is a substituted or unsubstituted C1 to C20 alkyl group, a substituted or unsubstituted C2 to C20 alkenyl group, or a substituted or unsubstituted C2 to C20 alkynyl group, and
R^{1b} is hydrogen or a C1 to C6 alkyl group.

8. The stretchable insulating film of claim 7, wherein
in the substituted or unsubstituted C1 to C20 alkyl group, a substituted or unsubstituted C2 to C20 alkenyl group, or a substituted or unsubstituted C2 to C20 alkynyl group of R^{1a} of Chemical Formula 1A, at least one methylene (—CH₂—) group is replaced by ether (—O—), sulfide (—S—), sulfonyl (—S(═O)₂—), carbonyl (—C(═O)—), sulfoxide (—S(═O)—), ester (—C(═O)O—), amide (—C(═O)NR—), wherein R is hydrogen, a C1 to C10 linear or branched alkyl group, or a C2 to C10 linear or branched alkenyl group, imine (—NR—), wherein R is hydrogen, a C1 to C10 linear or branched alkyl group, or a C2 to C10 linear or branched alkenyl group, phosphate (—P(═O)(OR)O₂—), wherein R is hydrogen, a C1 to C10 linear or branched alkyl group, or a C2 to C10 linear or branched alkenyl group, or any combination thereof.

9. The stretchable insulating film of claim 7, wherein
in Chemical Formula 1A, R^{1a} is:
a C1 to C20 linear or branched alkyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof;
a C2 to C20 linear or branched cyanoalkenyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof; or
a C2 to C20 linear or branched cyanoalkynyl group substituted with a halogen, a cyano group, a hydroxy group, an epoxy group, an amino group, a C1 to C10 alkyl group, a C4 to C10 cycloalkyl group, a C3 to C10 heterocycloalkyl group, a C6 to C10 aryl group, a C3 to C10 heteroaryl group, or any combination thereof.

10. The stretchable insulating film of claim 7, wherein
the alkenyl group-containing monomer is a compound represented by Chemical Formula 2A or 2B: 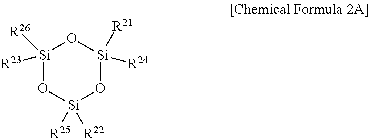
wherein, in Chemical Formula 2A,
R²¹ to R²⁶ are each independently hydrogen, a substituted or unsubstituted C1 to C20 linear or branched alkyl group or a substituted or unsubstituted C2 to C20 alkenyl group, provided at least one of R²¹ to R²⁶ is a substituted or unsubstituted C2 to C20 alkenyl group, 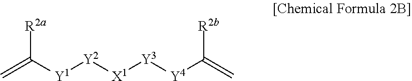
wherein, in Chemical Formula 2B,
X¹ is —O—, —(CR^{x}R^{y})ₙ₁— (wherein R^{x} and R^{y} are each independently hydrogen or a substituted or unsubstituted C1 to C20 alkyl group, and n1 is an integer of 1 to 20), a C4 to C10 cycloalkylene group, a C3 to C10 heterocycloalkylene group, a C6 to C10 arylene group, a C3 to C10 heteroarylene group, or phosphate (—P(═O)(OR)O₂—), (wherein R is hydrogen, a C1 to C10 linear or branched alkyl group, or a C2 to C10 linear or branched alkenyl group),
Y¹ to Y⁴ are each independently ether (—O—), carbonyl (—C(═O)—), ester (—C(═O)O—), or —(CR^{x}R^{y})ₙ₂— (wherein R^{x} and R^{y} are each independently hydrogen or a substituted or unsubstituted C1 to C20 alkyl group, and n2 is an integer of 1 to 20), and
R^{2a} and R^{2b} are each independently hydrogen or C1 to C6 alkyl group.

11. The stretchable insulating film of claim 10, wherein
the alkenyl group-containing monomer is the compound represented by Chemical Formula 2B,
in Chemical Formula 2B, X¹ is —(CR^{x}R^{y})ₙ₁— and at least one of Y¹ to Y⁴ is —(CR^{x}R^{y})ₙ₂—,
in Chemical Formula 2B, when n1 or n2 is 3 or more and 20 or less, at least one CR^{x}R^{y} is replaced by ether (—O—), sulfide (—S—), sulfonyl (—S(═O)₂—), carbonyl (—C(═O)—), sulfoxide (—S(═O)—), ester (—C(═O)O—), amide (—C(═O)NR—), wherein R is hydrogen, a C1 to C10 linear or branched alkyl group, or a C2 to C10 linear or branched alkenyl group, imine (—NR—), wherein R is hydrogen, a C1 to C10 linear or branched alkyl group, or a C2 to C10 linear or branched alkenyl group, phosphate (—P(=O)(OR)O₂—), wherein R is hydrogen, a C1 to C10 linear or branched alkyl group, or a C2 to C10 linear or branched alkenyl group, or any combination thereof.

12. The stretchable insulating film of claim 3, wherein
the elastomer includes the elastomer having the ester moiety and the elastomer having the ester moiety is prepared by polymerizing a carboxylic acid monomer and a hydroxyl group-containing monomer.

13. The stretchable insulating film of claim 1, wherein
the cyclic siloxane polymer framework includes a structural unit represented by Chemical Formula 3: 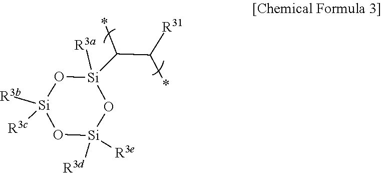
wherein, in Chemical Formula 3,
R^{3a} to R^{3e} are each independently hydrogen, a substituted or unsubstituted C1 to C20 alkyl group, a substituted or unsubstituted C2 to C20 alkenyl group, a substituted or unsubstituted C6 to C20 aryl group, a substituted or unsubstituted C3 to C20 heteroaryl group, a substituted or unsubstituted C3 to C20 cycloalkyl group, or a substituted or unsubstituted C3 to C20 heterocycloalkyl group, and
R³¹ is hydrogen or a C1 to C6 alkyl group.

14. The stretchable insulating film of claim 1, wherein
at the interface of the first insulating layer and the second insulating layer, the cyclic siloxane polymer forms a structure partially penetrating into the elastomer.

15. The stretchable insulating film of claim 1, wherein
a difference between elongation rates of the first insulating layer and the second insulating layer is in the range of about 25% to about 100%.

16. The stretchable insulating film of claim 1, wherein
a thickness of the first insulating layer is in the range of about 100 nm to about 1000 nm, and
a thickness of the second insulating layer is in the range of about 10 nm to about 200 nm.

17. The stretchable insulating film of claim 1, further comprising:
a self-assembled monolayer on the second insulating layer.

18. An electronic device comprising:
the stretchable insulating film according to claim 1.

19. The electronic device of claim 18, wherein
the electronic device includes an optoelectronic device, a light emitting device, a sensor, a thin film transistor, or an attachable device.

20. A method of manufacturing a stretchable insulating film, comprising
forming a first insulating layer by coating a composition including an elastomer or depositing the elastomer; and
forming a second insulating layer including a cyclic siloxane polymer, the forming the second insulating layer including injecting a cyclic siloxane monomer and an initiator on the first insulating layer into a reactor equipped with a heat source and performing a polymerization reaction by low-temperature vapor deposition.
